(19) United States
(12) Patent Application Publication
(10) Pub. No.: US 2009/0002527 A1
(43) Pub. Date: Jan. 1, 2009

(54) SOLID-STATE IMAGE SENSOR AND METHOD OF REMOVING DARK CURRENT COMPONENT

(75) Inventor: Tsuyoshi Higuchi, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED, Kawasaki-shi (JP)

(21) Appl. No.: 12/146,499

(22) Filed: Jun. 26, 2008

Related U.S. Application Data
(63) Continuation of application No. PCT/JP2005/023921, filed on Dec. 17, 2005.

(51) Int. Cl. H04N 9/64; H04N 5/335

(52) U.S. Cl. 348/243; 348/308; 348/E05.091; 348/E09.037

(57) ABSTRACT

A solid-state image sensor where dark current components fluctuating due to temperature changes are removed from pixel signals without reducing resolution during AD conversion. The sensor has a DA converter for generating a reference signal that increases at a constant slope from a predetermined initial signal level, a comparator for comparing the reference signal with a pixel signal, a counter for performing a counting operation in synchronization with increase in the reference signal, a latch circuit for holding as a quantized value of the pixel signal a discrete value at the time when the reference signal and the pixel signal coincide with each other, an average calculator for calculating an average of the quantized values of pixel signals read out from plural light-shielded pixels, and a reference signal adjuster for setting based on the average the initial signal level of the reference signal compared with the pixel signal read out from a light-receiving pixel.

This application is a continuing application, filed under 35 U.S.C. §111(a), of International Application PCT/JP2005/023921, filed Dec. 27, 2005.

### BACKGROUND

1. Field

The embodiments discussed herein are directed to a solid-state image sensor and a method of removing dark current components. The embodiments may relate to a solid-state image sensor using an analog-digital converter provided for each column of a pixel array. The embodiment may pertain to a method of removing dark current components of the solid-state image sensor.

2. Description of the Related Art

For a solid-state image sensor such as a CMOS (Complementary Metal-Oxide Semiconductor) image sensor, there is known a sensor with an analog-digital converter provided for each column of a pixel array, namely, a so-called column AD (analog-digital) converter (see, e.g., Japanese Unexamined Patent Publications No. 2000-349638).

FIG. 11 illustrates a schematic structure of a digital column AD converter in a conventional solid-state image sensor.

The digital column AD converter has a comparator 51 and a latch circuit 52. Each of the comparator 51 and the latch circuit 52 is provided for each column of a pixel array (not illustrated) in which a plurality of pixels for converting an optical signal into an electric signal by photoelectric conversion are arranged in a matrix form.

The comparator 51 compares a pixel signal from the pixel array (not illustrated) with a reference signal (ramp wave) that increases at a constant slope from a predetermined initial signal level in synchronization with a discrete value, and outputs the comparison results.

The latch circuit 52 receives the comparison results by the comparator 51 and the discrete values. Then, the circuit 52 holds, as a quantized value indicating a size of the pixel signal, the discrete value at the time when the pixel signal and the reference signal coincide with each other.

FIG. 12 illustrates a state of AD conversion using a column AD converter of a conventional solid-state image sensor.

In FIG. 12, the vertical axis represents the voltage [V], and the horizontal axis represents the discrete value.

A pixel signal from a light-receiving pixel is detected as a signal containing an offset component due to the influence of dark current. Further, the pixel signal is read out at a voltage level in a range of the shaded area in FIG. 12, for example, according to the amount of light received and is input to the column AD converter. The comparator 51 of the column AD converter illustrated in FIG. 11 compares the input pixel signal with reference signal. The latch circuit 52 latches a discrete value at the time when the input pixel signal and reference signal coincide with each other, and outputs the discrete value as a quantized value of the pixel signal. A dark current is strongly affected by temperature changes and a voltage level of the actual offset voltage (actual offset level) fluctuates due to temperature changes. Therefore, in the column AD converter of the conventional solid-state image sensor, a constant voltage level (analog offset level) set with some margin from the actual offset level as illustrated in FIG. 12 is set as an initial signal level of the reference signal so as to cover the fluctuation in voltage levels of pixel signals from the light-receiving pixels due to temperature changes.

However, when such an analog offset level is set, the resulting actual quantization level is less than the maximum quantization level by an offset as illustrated in FIG. 12. As a result, the resolution is reduced to cause reduction in image quality due to reduction in the resolution.

### SUMMARY

It is an aspect of the embodiments discussed herein to provide a solid-state image sensor using an analog-digital converter provided for each column of a pixel array, including: a reference signal generator for generating a reference signal that increases at a constant slope from a predetermined initial signal level; a comparator for comparing the reference signal with a pixel signal; a counter for performing a counting operation in synchronization with increase in the reference signal; a holding section for holding as a quantized value of the pixel signal a discrete value at the time when the reference signal and the pixel signal coincide with each other; an average calculator for calculating an average of the quantized values of the pixel signals read out from plural light-shielded pixels; and a reference signal adjuster for setting based on the average the initial signal level of the reference signal compared with the pixel signal read out from a light-receiving pixel.

These together with other aspects and advantages which will be subsequently apparent, reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 illustrates a structure of an essential part of a solid-state image sensor according to a first embodiment.

FIG. 2 illustrates one example of a pixel array.

FIG. 3 is a flowchart illustrating an AD conversion process of the solid-state image sensor according to the first embodiment.

FIG. 4 illustrates a state of AD conversion of pixel signals from light-shielded pixels.

FIG. 5 illustrates a state of AD conversion of pixel signals from light-receiving pixels.

FIG. 6 illustrates a structure of an essential part of a solid-state image sensor according to a second embodiment.

FIG. 7 is a flowchart illustrating an AD conversion process of the solid-state image sensor according to the second embodiment.

FIG. 8 illustrates a state of AD conversion of pixel signals from light-shielded pixels.

FIG. 9 illustrates a state of AD conversion of pixel signals from light-receiving pixels.

FIG. 10 illustrates one example of the pixel array in which plural light-shielded pixel regions are arranged.

FIG. 11 illustrates a schematic structure of a digital column AD converter in a conventional solid-state image sensor.

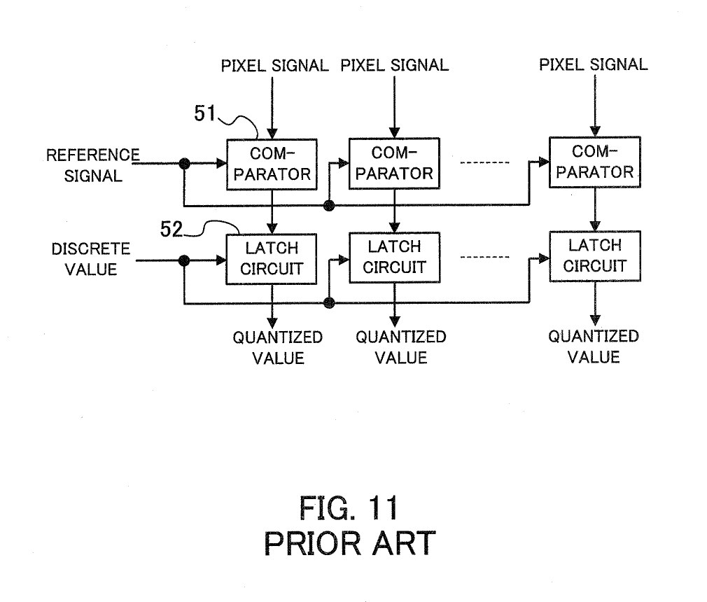

FIG. 12 illustrates a state of AD conversion using a column AD converter of the conventional solid-state image sensor.

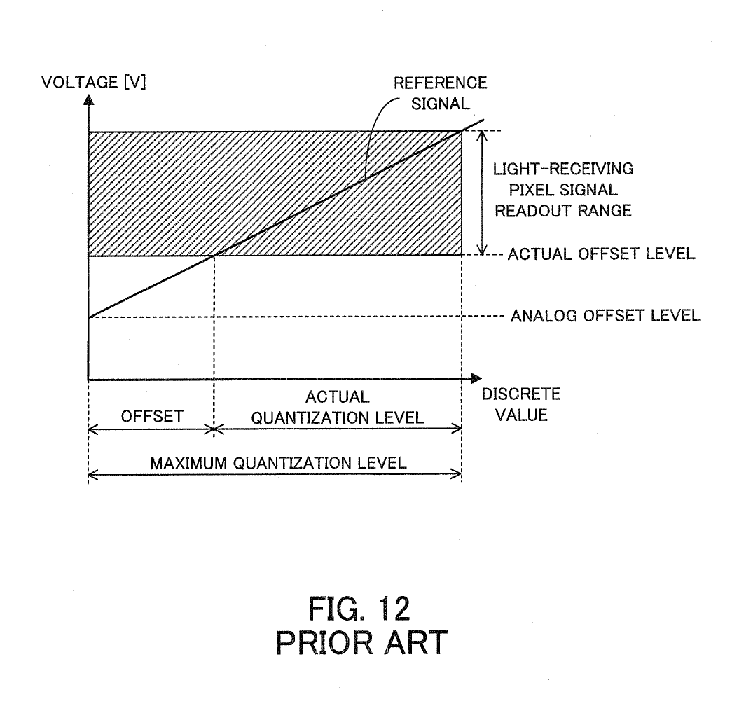

### DESCRIPTION OF THE EMBODIMENTS

Embodiments will be described below with reference to the accompanying drawings, wherein like reference numerals refer to like elements throughout.

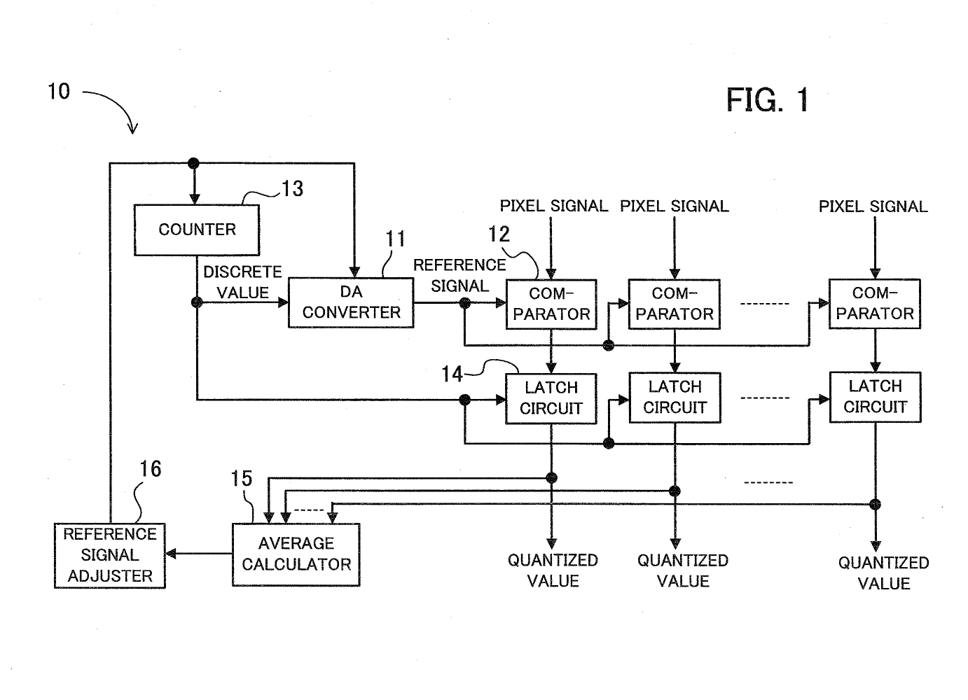

FIG. 1 illustrates a structure of an essential part of a solid-state image sensor according to a first embodiment.

A solid-state image sensor 10 according to the first embodiment has a DA converter 11, a comparator 12, a counter 13 and a latch circuit 14. Further, the solid-state image sensor 10 according to the first embodiment has an average calculator 15 and a reference signal adjuster 16.

The DA converter 11 performs DA conversion based on a discrete value of the counter 13 and generates a reference signal (ramp wave) that increases at a constant slope from a predetermined initial signal level.

The comparator 12 provided for each column compares the reference signal with a pixel signal read out from a pixel array.

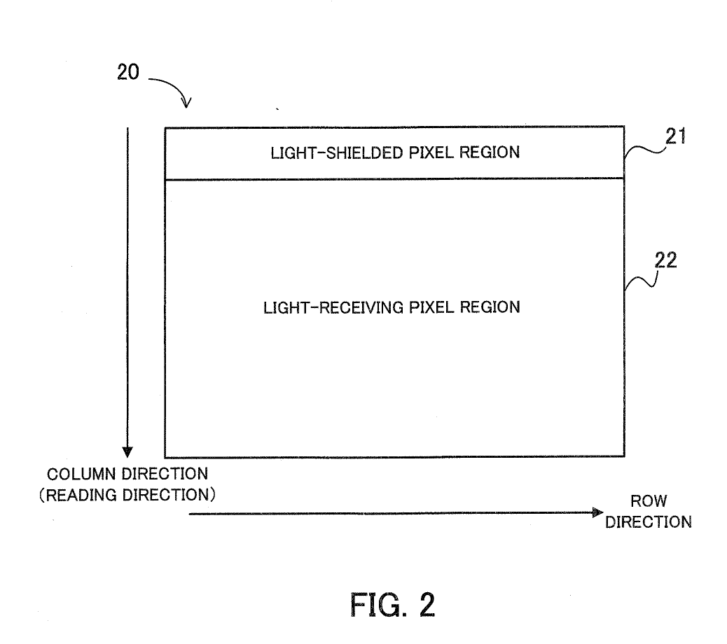

FIG. 2 illustrates one example of a pixel array.

A pixel array 20 comprises a light-shielded pixel region 21 and a light-receiving pixel region 22. In each region, pixels (not illustrated) including MOS transistors or photodiodes are arranged in a matrix form. The light-shielded pixel region 21 is a region in which pixels shielded from light (light-shielded pixels) to measure a black level are arranged. The light-receiving pixel region 22 is a region in which pixels irradiated with light (light-receiving pixels) are arranged.

From the pixel array 20, pixel signals are read out one line at a time in the column direction as illustrated in FIG. 2. For example, each of the pixel signals from thousands of columns is input to the comparator 12 in each column via a readout circuit (not illustrated).

Returning to FIG. 1, the counter 13 performs a counting operation in synchronization with increase in the reference signal.

The latch circuit 14 provided for each column holds as a quantized value (digital value) of the pixel signal a discrete value at the time when the reference signal and the pixel signal coincide with each other.

The average calculator 15 calculates an average of the quantized values (hereinafter, may be also referred to as a light-shielded pixel digital value) of pixel signals read out from plural light-shielded pixels (e.g., for thousands of columns).

The reference signal adjuster 16 sets, based on the average calculated by the average calculator 15, the initial signal level of the reference signal compared with the pixel signal read out from a light-receiving pixel.

That is, the average calculator 15 and the reference signal adjuster 16 have a function of determining a boundary value in a quantization range of AD conversion based on the light-shielded pixel digital value.

The average calculator 15 and the reference signal adjuster 16 may be integrated into a digital control circuit (not illustrated) that controls the whole of the solid-state image sensor 10.

Hereinafter, there will be described a pixel signal read-out operation, particularly, an AD conversion process of the solid-state image sensor 10 according to the first embodiment.

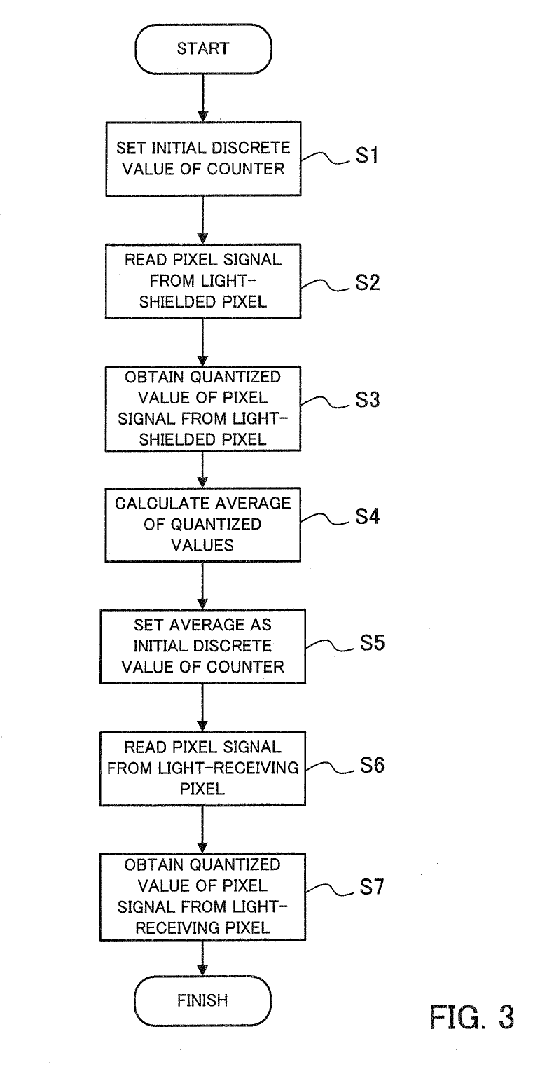

FIG. 3 is a flowchart illustrating the AD conversion process of the solid-state image sensor according to the first embodiment.

First, the reference signal adjuster 16 sets an initial discrete value of the counter 13 to a default value (e.g., zero) (step S1).

Then, the readout of pixel signals from the light-shielded pixels in the light-shielded pixel region 21 as illustrated in FIG. 2 is first performed by the readout circuit (not illustrated) (step S2).

Then, the quantized values of pixel signals from the light-shielded pixels are obtained by AD conversion (step S3).

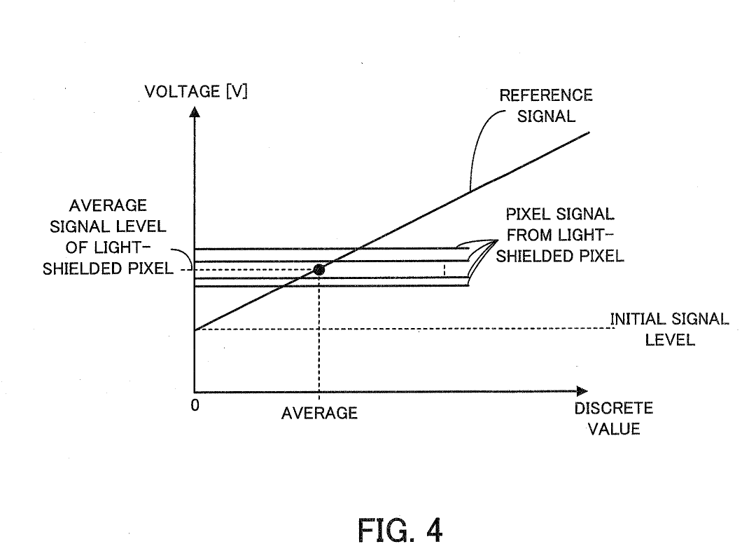

FIG. 4 illustrates a state of AD conversion of pixel signals from the light-shielded pixels.

In FIG. 4, the vertical axis represents the voltage [V], and the horizontal axis represents the discrete value by the counter 13.

In the AD conversion, the DA converter 11 generates a reference signal that increases at a constant slope from a given initial signal level in synchronization with the discrete value. The initial signal level and slope of the reference signal are set, for example, by the reference signal adjuster 16. When the pixel signal from the light-shielded pixel is input to the comparator 12, the counter 13 starts a counting operation to obtain a discrete value. Then, the comparator 12 compares the reference signal generated by the DA converter 11 based on this discrete value with the input pixel signal. When values of the reference signal and the pixel signal coincide with each other, the latch circuit 14 holds the then discrete value as the quantized value of the input pixel signal.

Next, the average calculator 15 obtains from each of the latch circuits 14 the quantized values of pixel signals from the light-shielded pixels and calculates an average of the quantized values (step S4).

The reference signal adjuster 16 sets the obtained average of the light-shielded pixel digital values as an initial discrete value of the counter 13 (step S5). That is, the calculator 15 and the adjuster 16 determine a minimum value in a quantization range of AD conversion based on the light-shielded pixel digital value.

Next, the readout of pixel signals from the light-receiving pixels is performed (step S6). Then, the quantized values of pixel signals from the light-receiving pixels are obtained by AD conversion (step S7).

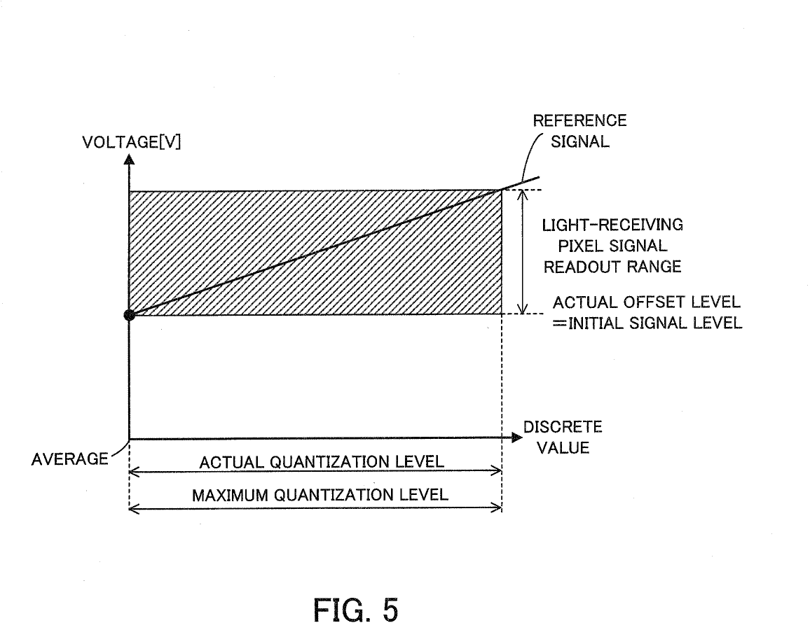

FIG. 5 illustrates a state of AD conversion of pixel signals from the light-receiving pixels.

In FIG. 5, the vertical axis represents the voltage [V], and the horizontal axis represents the discrete value by the counter 13.

The reference signal adjuster 16 sets a signal level of the reference signal in the calculated average (average signal level of pixel signals from the light-shielded pixels) as an initial signal level of the reference signal used for AD conversion of pixel signals from the light-receiving pixels. Further, the adjuster 16 may set a slope (gain) of the reference signal depending on the desired quantization level. Then, the DA converter 11 generates the reference signal based on the discrete value of the counter 13 with the calculated average set as the initial discrete value.

Using the thus set reference signal, the quantized values of pixel signals from the light-receiving pixels in the light-receiving pixel region 22 as illustrated in FIG. 2 are obtained by the comparator 12 and the latch circuit 14. After obtaining the quantized value, the average is subtracted from the obtained quantized value to equalize the black levels.

Through the above-described process, the actual offset level and the initial signal level of the reference signal can be matched in the AD conversion of pixel signals from the light-receiving pixels. Therefore, while equalizing the maximum quantization level and the actual quantization level, dark current components can be removed. Accordingly, the resolution during the AD conversion can be prevented from being reduced due to temperature changes. Thus, a picked-up image with high resolution and high image quality can be obtained.

The adjuster 16 may add a margin to the calculated average in setting the initial signal level of the reference signal to prevent black collapsing due to fluctuation in the quantized values of pixel signals from the light-shielded pixels. This margin is much smaller than a margin conventionally set to cover fluctuation in the dark current due to temperature changes.

Further, the adjuster 16, since a margin required to cover a fluctuation range of the quantized values of pixel signals from the light-shielded pixels changes depending on the slope (gain) of the reference signal, may set this margin depending on the slope of the reference signal. For example, when the slope of the reference signal is steep, a small margin is added to the calculated average set as the initial discrete value of the counter 13 whereas when the slope is gentle, a large margin is added.

Next, a solid-state image sensor according to a second embodiment will be described.

For a solid-state image sensor using a digital column AD converter, there is known a sensor having a constant current generating circuit for generating a reference signal. Also in that case, dark current components can be removed by the following structure without reducing resolution during the AD conversion.

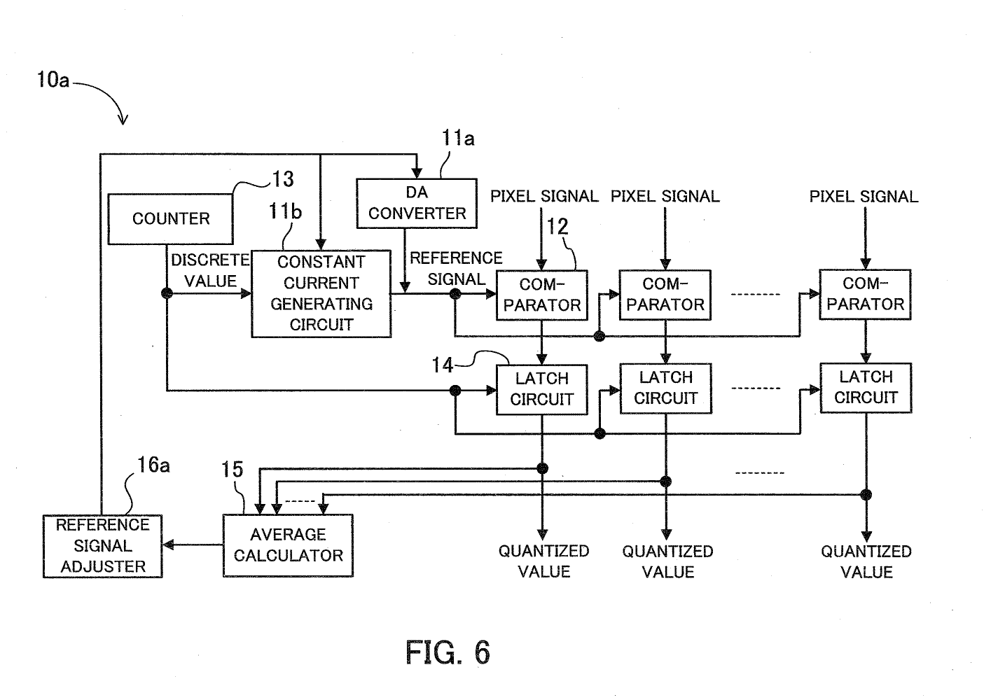

FIG. 6 illustrates a structure of an essential part of the solid-state image sensor according to the second embodiment.

In FIG. 6, the same elements as those of the solid-state image sensor 10 according to the first embodiment are indicated by the same reference numerals as in FIG. 1 and the description is omitted.

A solid-state image sensor 10a according to the second embodiment has two circuits for generating a reference signal, namely, a DA converter 11a and a constant current generating circuit 11b.

The DA converter 11a generates under the control of a reference signal adjuster 16a a reference signal used for AD conversion of pixel signals from the light-shielded pixels. Because the reference signal is used for AD conversion of pixel signals from the light-shielded pixels, the converter 11a may be a converter having low resolution. Accordingly, generation of the reference signal can be realized by a DA converter with a small circuit scale.

The constant current generating circuit 11b generates a reference signal used for AD conversion of pixel signals from the light-receiving pixels.

The reference signal adjuster 16, based on an average of the quantized values obtained as a result of AD conversion of pixel signals from the light-shielded pixels, sets an initial signal level of the reference signal generated by the constant current generating circuit 11b.

Hereinafter, there will be described an operation of the solid-state image sensor 10a according to the second embodiment.

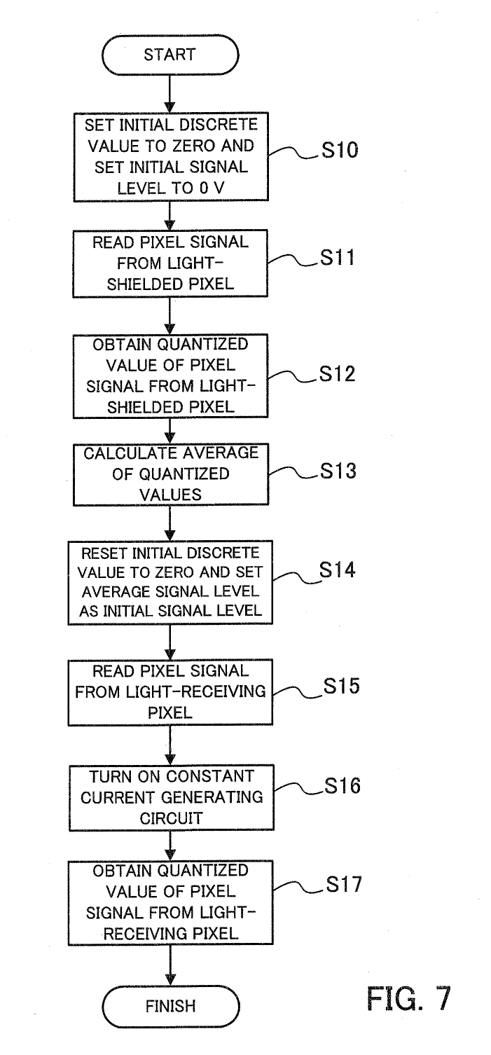

FIG. 7 is a flowchart illustrating the AD conversion process of the solid-state image sensor according to the second embodiment.

First, the reference signal adjuster 16a sets an initial discrete value of the counter 13 to zero and sets an initial signal level of the reference signal to 0 V (step S10).

Then, the readout of pixel signals from the light-shielded pixels in the light-shielded pixel region 21 as illustrated in FIG. 2 is first performed by the readout circuit (not illustrated) (step S11). Then, the quantized values of pixel signals from the light-shielded pixels are obtained by AD conversion (step S12).

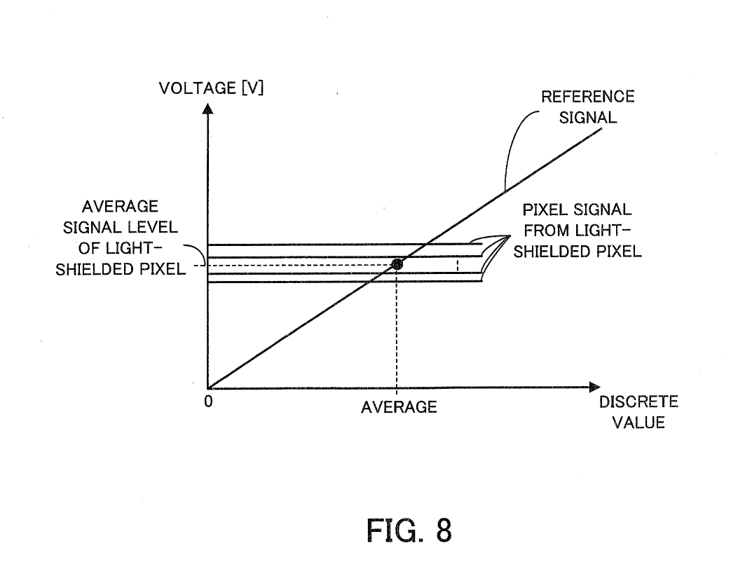

FIG. 8 illustrates a state of AD conversion of pixel signals from the light-shielded pixels.

In FIG. 8, the vertical axis represents the voltage [V], and the horizontal axis represents the discrete value by the counter 13.

In the AD conversion, the DA converter 11a generates a reference signal that increases at a constant slope from 0 V in synchronization with the discrete value. The slope of the reference signal is set by the reference signal adjuster 16a. When the pixel signal from the light-shielded pixel is input to the comparator 12, the counter 13 starts a counting operation to obtain a discrete value. Then, the comparator 12 compares the reference signal generated by the DA converter 11a based on this discrete value with the input pixel signal. When values of the reference signal and the pixel signal coincide with each other, the latch circuit 14 holds the then discrete value as the quantized value of the input pixel signal.

During the AD conversion of pixel signals from the light-shielded pixels, the constant current generating circuit 11b is turned off.

Next, the average calculator 15 obtains from each of the latch circuits 14 the quantized values of pixel signals from the light-shielded pixels, and calculates an average of the quantized values (step S13).

The reference signal adjuster 16a resets the initial discrete value of the counter 13 to zero and sets a signal level of the reference signal in the calculated average (average signal level of pixel signals from the light-shielded pixels) as an initial signal level of the reference signal generated by the constant current generating circuit 11b (step S14).

Next, the readout of pixel signals from the light-receiving pixels is performed (step S15). Then, the constant current generating circuit 11b is turned on (step S16). Then, the quantized values of pixel signals from the light-receiving pixels are obtained by AD conversion (step S17).

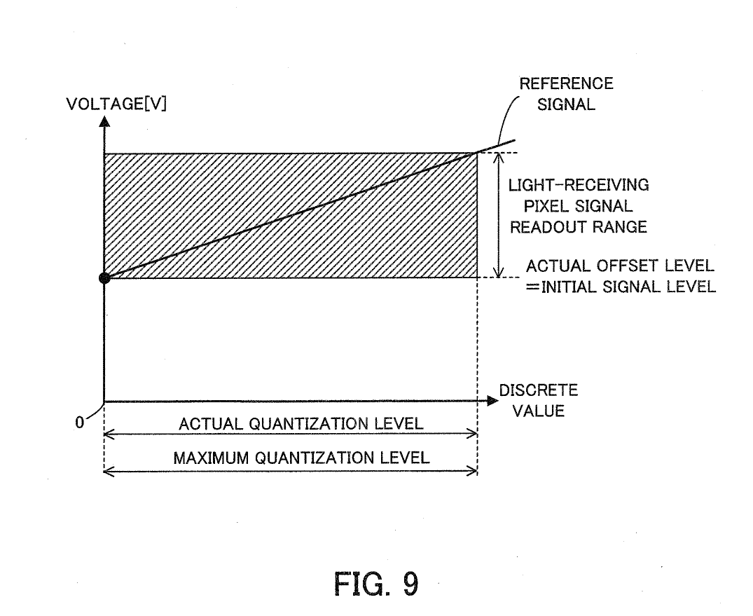

FIG. 9 illustrates a state of AD conversion of pixel signals from the light-receiving pixels.

In FIG. 9, the vertical axis represents the voltage [V], and the horizontal axis represents the discrete value by the counter 13.

The constant current generating circuit 11b generates a reference signal that increases at a constant slope from the initial signal level set by the reference signal adjuster 16a.

Using the thus set reference signal, the quantized values of pixel signals from the light-receiving pixels in the light-receiving pixel region 22 as illustrated in FIG. 2 are obtained by the comparator 12 and the latch circuit 14. Unlike the solid-state image sensor 10 according to the first embodiment, since the discrete value is counted from zero, the average need not be subtracted from the obtained quantized value in the solid-state image sensor 10a according to the second embodiment.

Through the above-described process, the actual offset level and the initial signal level of the reference signal can be matched in the AD conversion of pixel signals from the light-receiving pixels. Therefore, while equalizing the maximum quantization level and the actual quantization level, dark current components can be removed. Accordingly, the resolution during the AD conversion can be prevented from being reduced due to temperature changes. Thus, a picked-up image with high resolution and high image quality can be obtained.

The adjuster 16a may add a margin to the calculated average in setting the initial signal level of the reference signal to prevent black collapsing due to fluctuation in the quantized values of pixel signals from the light-shielded pixels or due to control limit of the DA converter 11a. This margin is much smaller than a margin conventionally set to cover fluctuation in the dark current due to temperature changes.

Further, the adjuster 16a, since a margin required to cover a fluctuation range of the quantized values of pixel signals from the light-shielded pixels changes depending on the slope (gain) of the reference signal, may set this margin depending on the slope of the reference signal. For example, when the slope of the reference signal is steep, a small margin is added to the calculated average whereas when the slope is gentle, a large margin is added.

In the solid-state image sensors 10 and 10a according to the first and the second embodiments, when a moving image is taken, the above-described setting of the initial signal level of the reference signal may be performed for each frame. For example, the setting of the initial signal level is performed at the head of readout of pixel signals in a frame. Alternatively, the setting thereof is performed at the end of readout of pixel signals in a frame, and the AD conversion of pixel signals from the light-receiving pixels in the next frame is performed using the set initial signal level.

When the temperature change between frames is small, the setting of the initial signal level may be performed once every predetermined number of frames (e.g., once every 30 frames) for reduction in a processing time.

FIG. 2 illustrates a case where the light-shielded pixel region 21 is arranged on the upper side of the pixel array 20. The light-shielded pixel region 21 may be arranged, for example, on the lower side of the pixel array 20.

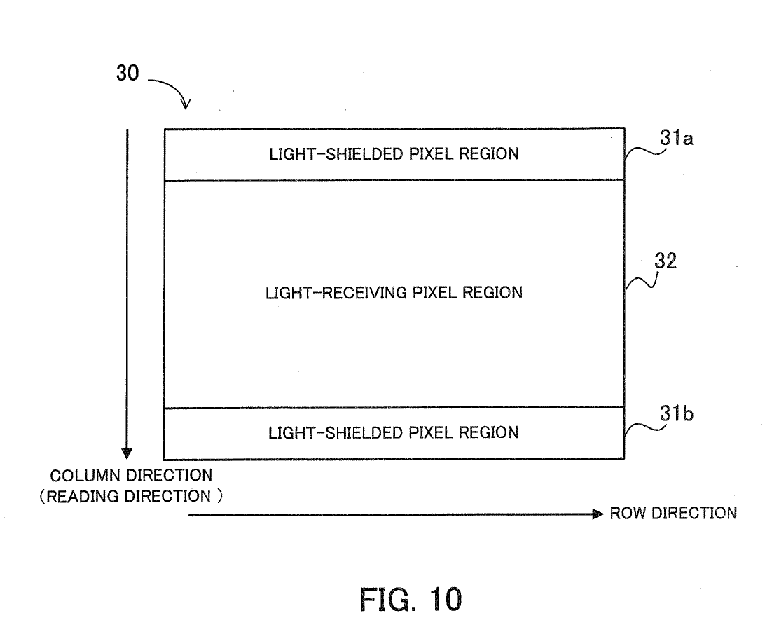

FIG. 10 illustrates one example of a pixel array in which plural light-shielded pixel regions are arranged.

A pixel array 30 comprises light-shielded pixel regions 31a and 31b and a light-receiving pixel region 32. The regions 31a and 31b are arranged on the upper and lower sides of the array 30 to sandwich the region 32. In the case of such a pixel array 30, for example, when calculating an average of the quantized values of pixel signals read out from the light-shielded pixels in both of the upper and lower regions 31a and 31b, dark current components can be more accurately estimated. In addition to this case, the embodiment is similarly applicable also to a case of using a light-shielded pixel region that surrounds the light-receiving pixel region 32.

According to the embodiment, there is provided a method of removing dark current components, comprising the steps of obtaining, before obtaining the quantized values of pixel signals read out from the light-receiving pixels, the quantized value of pixel signals read out from the light-shielded pixels; calculating an average of the quantized values; and setting, based on the calculated average, the initial signal level of the reference signal compared with the pixel signal read out from the light-receiving pixel. Therefore, dark current components fluctuating due to temperature changes can be removed without reducing the resolution during the AD conversion.

The foregoing is considered as illustrative only of the principles of the embodiment. Further, since numerous modifications and changes will readily occur to those skilled in the art, it is not desired to limit an invention to the exact construction and applications shown and described, and accordingly, all suitable modifications and equivalents may be regarded as falling within the scope of the invention in the appended claims and their equivalents.

What is claimed is:

1. A solid-state image sensor using an analog-digital converter provided for each column of a pixel array, comprising:
a reference signal generator for generating a reference signal that increases at a constant slope from a predetermined initial signal level;
a comparator for comparing the reference signal with a pixel signal;
a counter for performing a counting operation in synchronization with increase in the reference signal;
a holding section for holding as a quantized value of the pixel signal a discrete value at the time when the reference signal and the pixel signal coincide with each other;
an average calculator for calculating an average of the quantized values of the pixel signals read out from plural light-shielded pixels; and
a reference signal adjuster for setting based on the average the initial signal level of the reference signal compared with the pixel signal read out from a light-receiving pixel.

2. The solid-state image sensor according to claim 1, wherein:
the reference signal generator has a digital-analog converter that generates the reference signal based on the discrete value; and
the reference signal adjuster sets the average as an initial discrete value of the counter and sets a signal level of the reference signal in the average as the initial signal level of the reference signal used in readout of pixel signals from the light-receiving pixels.

3. The solid-state image sensor according to claim 2, wherein the reference signal adjuster sets the initial discrete value to a value obtained by adding a predetermined margin to the average.

4. The solid-state image sensor according to claim 3, wherein the reference signal adjuster sets the margin depending on a slope of the reference signal.

5. The solid-state image sensor according to claim 1, wherein:
the reference signal generator has a digital-analog converter and a constant current generating circuit, the digital-analog converter generating the reference signal when the pixel signal is read out from the light-shielded pixel, the constant current generating circuit generating the reference signal when the pixel signal is read out from the light-receiving pixel; and
the reference signal adjuster sets based on the average the initial signal level of the reference signal generated by the constant current generating circuit.

6. The solid-state image sensor according to claim 5, wherein the reference signal adjuster sets the initial signal level based on a value obtained by adding a predetermined margin to the average.

7. The solid-state image sensor according to claim 6, wherein the reference signal adjuster sets the margin depending on a slope of the reference signal.

8. The solid-state image sensor according to claim 1, wherein setting of the initial signal level is performed before starting readout of pixel signals from the light-receiving pixel in each frame.

9. The solid-state image sensor according to claim 1, wherein setting of the initial signal level is performed once every predetermined number of frames.

10. The solid-state image sensor according to claim 1, wherein the average calculator calculates the average of the quantized values of pixel signals in a light-shielded pixel region read out before pixel signals in a light-receiving pixel region.

11. The solid-state image sensor according to claim 1, wherein the average calculator calculates the average of the quantized values of pixel signals in plural light-shielded pixel regions arranged in the pixel array.

12. A method of removing dark current components of a solid-state image sensor, comprising the steps of:
comparing a pixel signal read out from a light-shielded pixel in a pixel array with a reference signal that increases at a constant slope from a predetermined initial signal level in synchronization with a discrete value, and obtaining, based on the discrete value at the time when the pixel signal and the reference signal coincide with each other, a quantized value of the pixel signal read out from the light-shielded pixel;
calculating an average of the quantized values of pixel signals read out from the plural light-shielded pixels;
setting based on the average the initial signal level of the reference signal compared with the pixel signal read out from a light-receiving pixel in the pixel array;
comparing the reference signal having the initial signal level set based on the average with the pixel signal read out from the light-receiving pixel; and
obtaining, based on the discrete value at the time when the reference signal and the pixel signal coincide with each other, the quantized value of the pixel signal read out from the light-receiving pixel.

13. The method according to claim 12, wherein a predetermined margin is added to the average.

14. The method according to claim 13, wherein the margin is set depending on an slope of the reference signal.

15. The method according to claim 12, wherein setting of the initial signal level is performed before starting readout of pixel signals from the light-receiving pixel in each frame.

16. The method according to claim 12, wherein setting of the initial signal level is performed once every predetermined number of frames.

17. The method according to claim 12, wherein the average of the quantized values of pixel signals in a light-shielded pixel region read out before pixel signals in a light-receiving pixel region is calculated.

18. The method according to claim 12, wherein the average of the quantized values of pixel signals in plural light-shielded pixel regions arranged in the pixel array is calculated.

19. A solid-state image sensor using an analog-digital converter provided for each column of a pixel array, comprising:
a calculator for reading out a pixel signal from a light-shielded pixel in the pixel array and calculating a light-shielded pixel digital value converted by the analog-digital converter; and
a boundary value calculator for determining a boundary value in a quantization range of the analog-digital converter based on the light-shielded pixel digital value calculated by the calculator.

20. The solid-state image sensor according to claim 19, wherein the boundary value calculator determines the light-shielded pixel digital value as a minimum value in the quantization range.
